(19) United States
(12) Patent Application Publication
(10) Pub. No.: US 2004/0057547 A1
(43) Pub. Date: Mar. 25, 2004

(54) Fractional frequency clock signal synthesizer and method of operation thereof

(75) Inventor: Lindor E. Henrickson, San Jose, CA (US)

Correspondence Address: HITT GAINES P.C., P.O. BOX 832570, RICHARDSON, TX, 75083, US

(73) Assignee: Agere Systems Inc., Allentown, PA

(21) Appl. No.: 10/252,344

(22) Filed: Sep. 23, 2002

(51) Int. Cl. H03D 3/24

(52) U.S. Cl. 375/376

(57) ABSTRACT

A local clock signal synthesizer, a method of generating fractional frequency local clock signals and a synchronous telecommunications system incorporating the synthesizer or the method. In one embodiment, the synthesizer includes: (1) a reference clock source that generates a reference clock signal, (2) a delay circuit, coupled to the reference clock source and having taps, that provides progressively delayed versions of the reference clock signal at the taps and (3) tap-select logic, coupled to the delay circuit, that traverses the taps to generate the local clock signal from the progressively delayed versions.

### TECHNICAL FIELD OF THE INVENTION

The present invention is directed, in general, to phase-locked loops and, more specifically, to a fractional frequency clock signal synthesizer, a method of generating fractional frequency clock signals and a synchronous telecommunications system incorporating the synthesizer or the method.

### BACKGROUND OF THE INVENTION

Two ways exist by which data can be communicated from a transmitter to a receiver: asynchronously or synchronously. Data communication is asynchronous when the transmitter and receiver employ separate time bases (clocks). While asynchronous data communication dispenses with the need for a synchronizing master clock signal to be transmitted with the data, the data instead is required to be bounded by control bits and typically buffered at both the transmitting and receiving ends. The control bits and buffering result in an overall reduction in data transmission rate.

Synchronous data communication occurs when the transmitter and receiver share the same time base. Synchronous data communication greatly reduces the need for buffering as described above and may simply utilize control bits for adding quality of service. Synchronous data communication, however, requires a master clock signal to be shared between the transmitter and receiver to ensure that they work harmoniously. While asynchronous communications systems have certainly found their place today, modern telecommunications systems and sophisticated computer networks predominantly use synchronous data communication due to the superior speed it offers.

Unfortunately, communicating a clock signal over distances can be challenging. A clock signal may be encoded in a square waveform and may be transmitted many miles over an electrical wire, optical fiber or wirelessly. The clock signal may be distributed with synchronous data or via a separate master clock network. In addition, the clock signal may be embedded within the synchronous data and extracted when needed. During its transmission, interference and transmission line impairments may serve to attenuate, disperse, distort and/or frequency-shift the clock signal, rendering it difficult to use or perhaps even to recognize at its destination.

Accordingly, it has become commonplace to employ circuits either to regenerate the master clock signal or use it merely to synchronize a local clock. Such local clock generating circuits often employ a phase-locked loop (PLL) in combination with a voltage-controlled crystal oscillator (VCXO), a delay-locked loop (DLL) or a fixed frequency crystal oscillator.

Some applications require great frequency agility on the part of the local clock signal. In other words, different frequencies may be needed at different times, typically to allow equipment to be “interoperable,” (function with systems or networks adhering to different standards). Conventional local clock signal generating circuits have attempted to meet this challenge by applying different integer multipliers to the frequency of a single reference clock to yield the various required local clock frequencies. The frequency of the reference clock is advantageously chosen to be the greatest common factor of the various local clock frequencies that are required to be generated.

Unfortunately, the success of this approach depends heavily upon the relationship between or among the required local clock frequencies, becoming markedly less desirable as the greatest common factor of the required local clock frequencies must decrease. In theory, a single reference clock could still be used provided its frequency is sufficiently low. However, low reference clock frequencies require extreme multiplication, which causes errors to occur in the resulting local clock frequencies. To avoid the extreme multiplication problem, conventional local clock generating circuits have employed multiple reference clocks of higher frequency. However, each additional reference clock adds size, cost and complexity to the overall circuit. Furthermore, if VCXOs or crystal oscillators (XOs) are used as reference clocks, circuit cost and size become an acute issue, because VCXOs and XOs are expensive and unable to be integrated with other circuitry onto the same chip.

Accordingly, what is needed in the art is a fundamentally new architecture for a local clock generating circuit. The circuit should ideally be integratable into a single chip, frequency-agile, and should not require multiple expensive, discrete-components such as VCXOs or fixed frequency XOs.

### SUMMARY OF THE INVENTION

To address the above-discussed deficiencies of the prior art, the present invention provides a local clock signal synthesizer, a method of generating fractional frequency local clock signals and a synchronous telecommunications system incorporating the synthesizer or the method. In one embodiment, the synthesizer includes: (1) a reference clock source that generates a reference clock signal, (2) a delay circuit, coupled to the reference clock source and having taps, that provides progressively delayed versions of the reference clock signal at the taps and (3) tap-select logic, coupled to the delay circuit, that traverses the taps to generate the local clock signal from the progressively delayed versions. For purposes of the present invention, “traverses” is defined as “temporarily couples the tap to the output of the circuit such that the signal at the tap temporarily becomes the local clock signal.” The resulting local clock signal is therefore an amalgam of the various progressively delayed versions that went into its creation.

The present invention therefore introduces a local clock signal synthesizer that builds local clock signals from a plurality of progressively delayed reference clock signals. By changing the direction and frequency of tap traversal, the tap-select logic is capable of generating a wide variety of high quality, local clock signal frequencies without requiring multiple VCXOs or fixed frequency XOs.

In one embodiment of the present invention, the reference clock signal has a frequency lower than a frequency of the local clock signal. Subject to practical considerations and any limitations that a particular application may have, the present invention can operate with a reference clock signal of any frequency.

In one embodiment of the present invention, the delay circuit is a delay-locked loop. Those skilled in the pertinent art are familiar with the structure and operation of delay-locked loops and will recognize their advantageous use in circuits constructed according to the principles of the present invention. Of course, other delay circuits fall within the broad scope of the present invention.

In one embodiment of the present invention, the delay circuit has at least 32 taps. In an embodiment to be illustrated in the Detailed Description that follows, the delay circuit has only four taps. Delay circuits having 64 or more taps may also prove advantageous in a particular application.

In one embodiment of the present invention, delays of the progressively delayed versions are evenly distributed along a single period of the reference clock signal. “Evenly distributed” means that a fixed delay separates each tap. Alternatively, the taps may be unevenly distributed, which may give rise to more sophisticated tap traversal schemes.

In one embodiment of the present invention, the tap-select logic comprises an up/down counter that traverses the taps sequentially. Alternatively, the tap-select logic may traverse the taps in any advantageous order.

In one embodiment of the present invention, the tap-select logic cycles through all of the taps to generate the local clock signal. Alternatively, the tap-select logic may employ more complex circuitry for skipping taps either conditionally or unconditionally.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

For a more complete understanding of the present invention, reference is now made to the following descriptions taken in conjunction with the accompanying drawings, in which:

FIG. 1 illustrates a block diagram of a synchronous telecommunication system that forms one environment within which a local clock signal synthesizer constructed according to the principles of the present invention may advantageously operate;

FIG. 2 illustrates a block diagram of a local clock signal synthesizer constructed according to the principles of the present invention;

FIGS. 3A and 3B together illustrate operation of the local clock signal synthesizer of FIG. 2 when the required local clock signal frequency is less than the reference clock frequency (FIG. 3A) and when the required local clock signal frequency is greater than the reference clock frequency (FIG. 3B); and

FIG. 4 illustrates a flow diagram of a method of generating fractional frequency local clock signals carried out according to the principles of the present invention.

### DETAILED DESCRIPTION

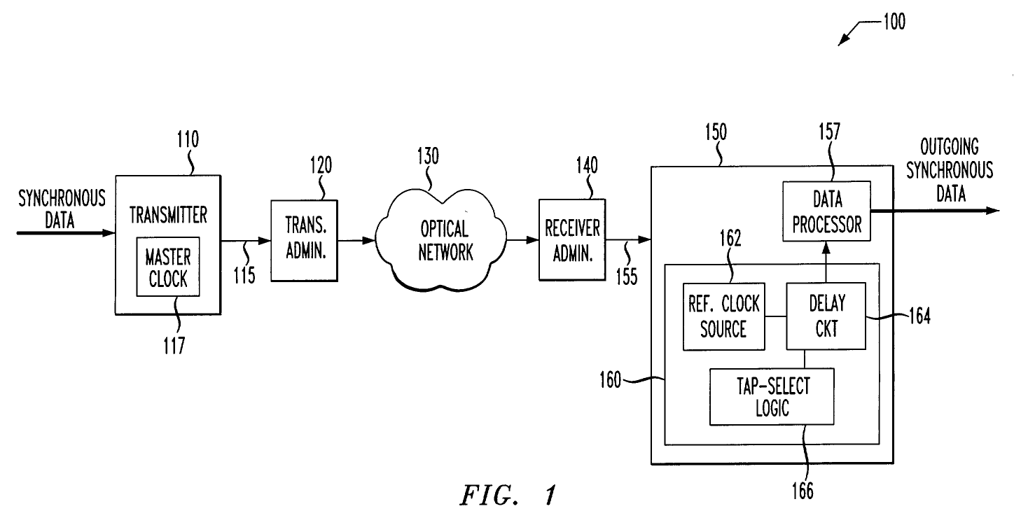

Referring initially to FIG. 1, illustrated is a synchronous telecommunications system, generally designated 100, that forms one environment within which a local clock signal synthesizer 160, constructed according to the principles of the present invention, may advantageously operate. The synchronous telecommunications system 100 includes a transmitter 110 having a transmit data channel 115, a transmitter administrator 120, an optical network 130, a receiver administrator 140 and a receiver 150 having a receive data channel 155. The transmitter 110 includes a master clock 117. The receiver 150 includes a data processor 157 and the local clock signal synthesizer 160. The local clock signal synthesizer 160 includes a reference clock source 162, a delay circuit 164 having taps and tap-select logic 166. The synchronous telecommunications system 100 is an optical system. However, one skilled in the pertinent art will understand that the local clock signal synthesizer 160 may advantageously operate in other synchronous telecommunications system employing other modes of transmission besides optical fiber including wireless, electrical wire or any combination of the three.

The transmitter 110 receives synchronous data and provides a transmit data channel 115 to the transmit administrator 120. The synchronous data may be digital information including music, voice or computer data. The transmit data channel 115 may be a single data channel or may be a plurality of parallel data channels. The transmitter 110 sends the synchronous data via the transmit data channel 115 to the transmitter administrator 120. The transmitter administrator 120 manages the conversion of the synchronous data from electrical data signals into optical data signals suitable for transmission over the optical network 130. The transmitter 110 and the transmitter administrator 120 process the synchronous data based on an input clock signal from the master clock 117. To insure the synchronous data is processed with the same time base during transmission and reception, the transmitter 110 may send the input clock signal with the synchronous data to the optical network 130. In some embodiments, the input clock signal may be sent via a separate master clock network. In other embodiments, the transmitter may embed the input clock signal within the synchronous data for extraction before processing of the synchronous data. Of course, components of the optical network 130 may also employ a local clock generating circuit to insure a harmonious clock signal with the master clock 117 for synchronous processing.

The optical network 130 may transmit the synchronous data and the input clock signal from the transmitter administrator 120 to the receiver administrator 140. The optical network 130 may vary in length depending on the remoteness of the receiver 150. The optical network 130 may be established within a single building. In other embodiments, the optical network 130 may provide long distance transmission between the receiver 150 remotely located from the transmitter 110. The receiver 150, for example, may be remotely located across town, in another city or in another state.

The rate of operation of the optical network 130 may also vary. For example, the synchronous telecommunications system 100 may support various Synchronous Optical Network (SONET) transmission rates ranging from about 51 Mb per second to about 40 Gb per second. Accordingly, the input clock signal of the master clock 117 will vary to control the synchronous processing of the various transmission rates.

The receiver administrator 140 receives the synchronous data and input clock signal and manages the conversion from optical data signals into electrical data signals for use by the receiver 150. In another synchronous telecommunications system, the synchronous data and the input clock signal may be received by other circuitry instead of the receiver administrator 140. For example, a receiving circuit may be a radio frequency front end of a radio frequency receiver. In the synchronous telecommunications system 100, the receiver administrator 140 sends the synchronous data and the input clock signal to the receiver 150 via the receive data channel 155. In some embodiments, the input clock signal may be embedded in the synchronous data. The receive data channel 155 may be a single data channel or may be a plurality of parallel data channels.

The receiver 150 employs the data processor 157 to process the received synchronous data resulting in outgoing synchronous data. The data processor 157 processes the received synchronous data based on a local clock signal generated by the local clock generating circuit 160. The local clock signal is generated to correspond with the input clock signal of the master clock 117 and insure the same time base at the receiver 150 and the transmitter 110. Due to the difficulty in constructing precisely independent matched clocks remotely located from each other, the input clock signal may be employed to provide a necessary coupling to the master clock 117. Even though the input clock signal was transmitted with the synchronous data, the local clock signal is used since the input clock signal may have been altered during transmission. For example, the input clock signal may have accumulated jitter from components of the optical network 130. In a preferred embodiment, the reference clock signal has a frequency lower than a frequency of the local clock signal.

The reference clock source 162 generates a reference clock signal for the local clock signal synthesizer 160. The delay circuit 164, coupled to the reference clock source 162, provides progressively delayed versions of the reference clock signal at the taps. The progressively delayed versions may be evenly distributed along a single period of the reference clock signal. In one embodiment, the delay circuit 164 may have at least 32 taps. In a preferred embodiment, the delay circuit 164 is a delay-locked loop (DLL).

The tap-select logic 166, coupled to the delay circuit 164, traverses the taps to generate the local clock signal from the progressively delayed versions. In a preferred embodiment, the tap-select logic 166 includes an up/down counter that sequentially traverses the taps. In some embodiments, the tap-select logic 166 cycles through all of the taps of the delay circuit 164 to generate the local clock signal.

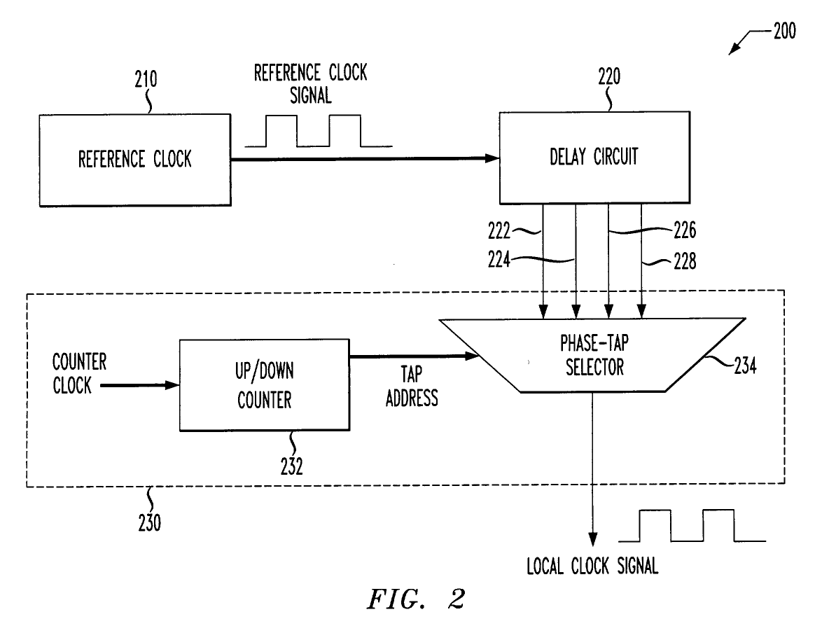

Turning now to FIG. 2, illustrated is a block diagram of a local clock signal synthesizer, generally designated 200, constructed according to the principles of the present invention. The local clock signal synthesizer 200 includes a reference clock source 210, a delay circuit 220 and tap-select logic 230. The delay circuit 220 includes taps designated by a first tap 222, a second tap 224, a third tap 226 and a fourth tap 228. The tap select logic 230 includes an up/down counter 232 and a phase-tap selector 234.

The reference clock source 210 generates a reference clock signal with a fixed frequency. In a preferred embodiment, the reference clock signal frequency is lower than a local clock signal frequency. In other embodiments, the reference clock signal frequency may be higher than or equal to the local clock signal frequency. The reference clock source 210 may be a conventional clock source that employs a phase locked loop to generate the reference clock signal. In an another embodiment, the reference clock source 210 may be a fixed frequency crystal oscillator. Coupled to the reference clock 210 is the delay circuit 220.

The delay circuit 220 provides progressively delayed versions of the reference clock signal at the taps. As stated above, the delay circuit 220 has four taps. Of course, the number of taps of the delay circuit 220 may vary with a variable, such as N representing the number of taps. In one embodiment, the delay circuit 220 may have at least 32 taps. The delay circuit 220 generates four equally spaced taps having a delay spacing equal to a selected reference clock signal period divided by four. The taps are electrical connections which permit the retrieval of the progressively delayed versions of the reference clock signal.

In a preferred embodiment, the delay circuit 220 may be a conventional delay-locked loop (DLL). One skilled in the pertinent art will understand the operation of a DLL. In other embodiments, the delay circuit 220 may be another type of delay circuit capable of providing progressively delayed versions of the reference clock signal. Coupled to the delay circuit 220 is the tap-select logic 230.

The tap-select logic 230 traverses the taps of the delay circuit 220 to generate the local clock signal from the progressively delayed versions of the reference clock signal. In a preferred embodiment, the tap-select logic 230 employs digital control circuitry. In the illustrated embodiment, the tap-select logic 230 includes the up/down counter 232 and the phase-tap selector 234. The up/down counter 232 may traverse the taps sequentially.

The up/down counter 232 may generate either an increasing or decreasing ramp of tap addresses based on the frequency of the desired local clock signal versus the frequency of the reference clock signal. The up/down counter 232 may employ the counter clock to generate the tap addresses. The counter clock may be externally generated or may be derived from either the taps of the delay circuit 220 or the local clock signal. Regardless the source, the counter clock assists in preventing cycle slip of the reference clock signal when traversing the taps.

When generating an increasing ramp, the up/down counter 232 may move to an address for the first tap 222 after generating an address for the fourth tap 228. In some embodiments, the up/down counter 232 may move past the first tap 222 address when generating addresses faster than one address per reference clock signal cycle. When generating a decreasing ramp, the up/down counter 232 moves to the address of the fourth tap 228 after generating the address of the first tap 222. In some embodiments, the up/down counter 232 may move past the fourth tap 228 address when operating faster than one tap address per reference clock signal cycle. The up/down counter 232, therefore, may wrap around the taps when generating an increasing or decreasing ramp of tap addresses.

The phase-tap selector 234 receives the tap addresses from the up/down counter 232 designating a tap. The phase-tap selector 234 traverses the designated tap of the delay circuit 220 such that the signal at the tap temporarily becomes the local clock signal. The local clock signal, therefore, may be the output of the phase-tap selector 234 at any given point in time.

The frequency of the local clock signal, as compared to the reference clock signal, may be shifted by an amount proportional to the rate of the increasing or decreasing ramp of tap addresses generated by the up/down counter 232. More specifically, the local clock signal may be proportional to the rate at which the tap addresses precess around the delay circuit 220 taps. For example, when the up/down counter 232 is generating an increasing ramp, the delay circuit 220 will expand the input period of the reference clock signal by the number of taps traversed per reference clock signal cycles. When the up/down counter is generating a decreasing ramp, the delay circuit 220 will compress the input period of the reference clock signal by the number of taps traversed per reference clock cycle. In summary, the local clock signal period, T_{local}, may be expressed as T_{local}=(T_{ref}+M*T_{ref}/4) resulting in Equation 1 when the up/down counter 232 is generating an increasing ramp and resulting in Equation 2 when the up/down counter 232 is generating a decreasing ramp.

T_{local}=T_{ref}*(1+M/4). Equation 1

T_{local}=T_{ref}*(1−M/4). Equation 2

In Equations 1 and 2, M represents a number of taps traversed per reference clock signal cycle, T_{ref} equals a period of the reference clock signal and four represents the number of taps in the delay circuit 220. The ratio, therefore, of the reference clock signal frequency to the local clock signal frequency may be expressed as F_{ref}/F_{local}=T_{local}/T_{ref} resulting in Equation 3. In the embodiment where M=0, the up/down counter 232 outputs a constant static tap address resulting in F_{ref}/F_{local}=1.0.

F_{ref}/F_{local}=(1±M/4). Equation 3

For general equations, the number of taps, 4, may be replaced by the variable N.

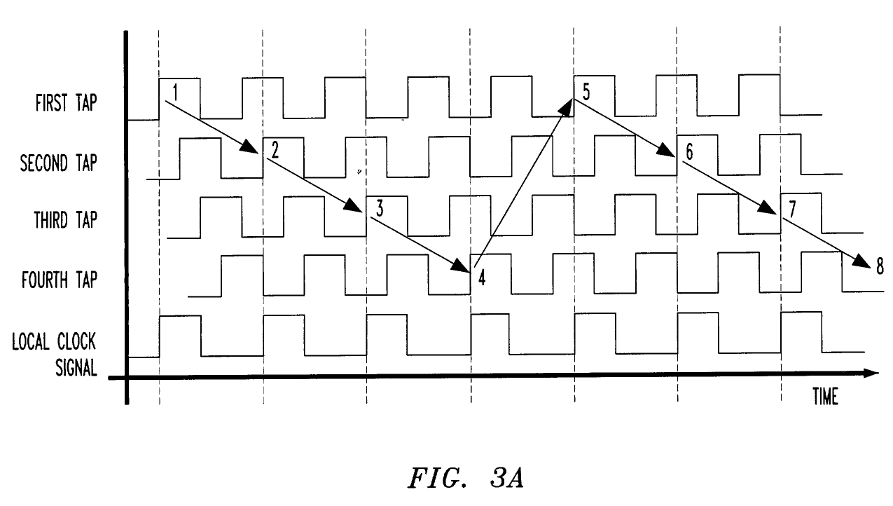

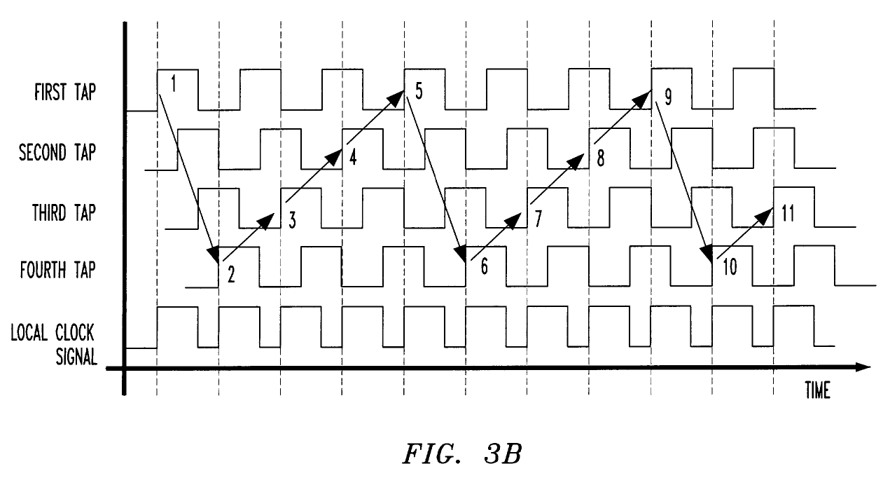

Turning now to FIGS. 3A and 3B, illustrated are the operation of the local clock signal synthesizer of FIG. 2 when the required local clock signal frequency is less than the reference clock frequency (FIG. 3A) and when the required local clock signal frequency is greater than the reference clock frequency (FIG. 3B). The horizontal axes for FIGS. 3A and 3B represents time and the vertical axes are the waveforms of the signals at the taps and the local clock signal. In FIGS. 3A and 3B, the up/down counter 232 traverses the taps sequentially at a rate of one tap per reference clock signal cycle. Of course, one skilled in the pertinent art will understand that the up/down counter 232 may traverse the taps at various rates or methods.

In FIG. 3A, the selection of the tap address by the up/down counter 232 follows the numbered Sequence Points 1 to 8. At Sequence Point one, the tap address of the first tap 222 is sent from the up/down counter 232 to the phase-tap selector 234 which traverses the first tap 222. Since the F_{local} is less than the F_{ref}, then the up/down counter 232 generates an increasing ramp of tap addresses. At Sequence Point two, therefore, the up/down counter 232 sends the address of the second tap 224 to the phase-tap selector 234 which traverses the second tap 224. The up/down counter 232 and the phase-tap selector 234 continue to traverse the taps in this manner until after traversing the fourth tap 228. At this point, the first tap 222 is traversed. In this way, the up/down counter 232 and phase-tap selector 234 cooperate to wrap around to the first tap 222 after traversing the fourth tap 228. The up/down counter 232 and the phase-tap selector 234 then continue through Sequence Points 5 through 8 in the same manner.

In FIG. 3B, the selection of the tap address by the up/down counter 232 follows the numbered Sequence Points 1 to 11. At Sequence Point 1, the tap address of the first tap 222 is sent from the up/down counter 232 to the phase-tap selector 234 which traverses the first tap 222. Since the F_{local} is greater than the F_{ref}, then the up/down counter 232 generates a decreasing ramp of tap addresses. When generating a decreasing ramp of tap addresses, the up/down counter 232 and the phase-tap selector 234 traverse the fourth tap 228 after traversing the first tap 222. In this way the up/down counter 232 and phase-tap selector 234 cooperate to wrap around to the fourth tap 228 after traversing to the first tap 222. At Sequence Point 2, therefore, the up/down counter 232 traverses the fourth tap 228 based on the received tap address. At Sequence Point 2, the up/down counter 232 and the phase-tap selector 234 then decreasingly traverse the taps until Sequence Point 5 when the first tap 222 is traversed. At this point, the up/down counter 232 and the phase-tap selector 234 then traverse the fourth tap 228 at Sequence Point 6. The process then continues in this manner through Sequence Point 11 as described above.

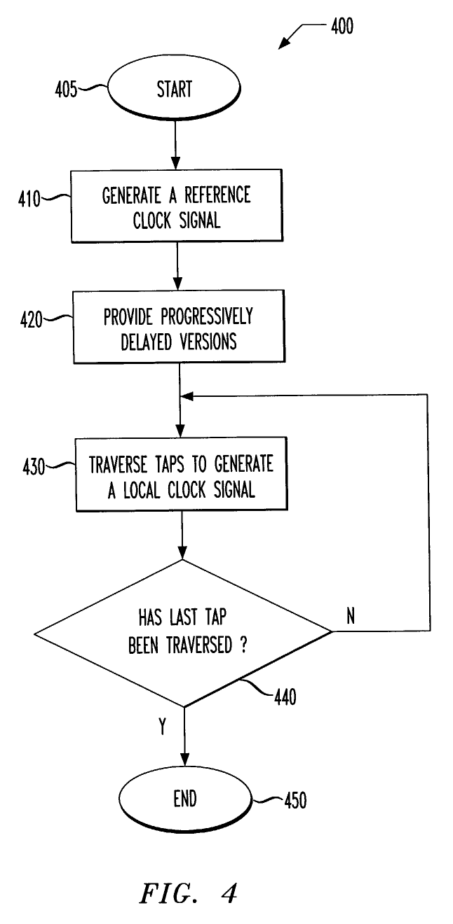

Turning now to FIG. 4, illustrated is a flow diagram of a method, generally designated 400, of generating fractional frequency local clock signals carried out according to the principles of the present invention. The method starts in a step 405 with an intent to generate fractional frequency local clock signals.

After starting, a reference clock signal is generated in a step 410. The reference clock signal may be generated by a reference clock source as previously described with respect to FIG. 2. Typically, the reference clock signal is generated with a fixed frequency. In a preferred embodiment, the reference clock signal has a frequency lower than a frequency of the local clock signal.

After generating a reference clock signal, progressively delayed versions of the reference clock signal are provided at taps of a delay circuit in a step 420. In a preferred embodiment, the delay circuit is a delay-locked loop. In one embodiment, the delay circuit has at least 32 taps. In another embodiment, the delays of the progressively delayed versions are evenly distributed along a single period of the reference clock signal. For example, for a delay circuit with 32 taps, the delay circuit may receive the reference clock signal and generate 32 equally spaced taps having a delay spacing equal to the period of the reference clock signal divided by 32. Of course, one skilled in the art will understand that the number of taps and the length of the delay spacings may vary.

After providing the progressively delayed versions, the taps are traversed to generate a local clock signal in a step 430. The taps may be traversed using a tap-select logic. In a preferred embodiment, the tap-select logic may employ an up/down counter that sequentially traverses the taps. In one embodiment, the tap-select logic may also employ a phase-tap selector.

After traversing the taps, a determination is made if all necessary taps have been traversed in a decisional step 440. In one embodiment, the tap-select logic cycles through each of the taps of the delay circuit to generate the local clock signal. In some embodiments, the taps may be traversed in an increasing order. In other embodiments, the taps may be traversed in a decreasing order. One skilled in the pertinent art will understand that the taps may be traversed in various ways and that every tap may not be traversed to generate the local clock signal.

If it is determined that each necessary tap has been traversed, then generating fractional frequency local clock signals ends in a step 450. Returning now to the decisional step 440, if it is determined that all of the taps have not been traversed, then the method 400 proceeds to step 430 and continues as before.

Although the present invention has been described in detail, those skilled in the art should understand that they can make various changes, substitutions and alterations herein without departing from the spirit and scope of the invention in its broadest form.

What is claimed is:

1. A local clock signal synthesizer, comprising:
a reference clock source that generates a reference clock signal;
a delay circuit, coupled to said reference clock source and having taps, that provides progressively delayed versions of said reference clock signal at said taps; and
tap-select logic, coupled to said delay circuit, that traverses said taps to generate said local clock signal from said progressively delayed versions.

2. The synthesizer as recited in claim 1 wherein said reference clock signal has a frequency lower than a frequency of said local clock signal.

3. The synthesizer as recited in claim 1 wherein said delay circuit is a delay-locked loop.

4. The synthesizer as recited in claim 1 wherein said delay circuit has at least 32 taps.

5. The synthesizer as recited in claim 1 wherein delays of said progressively delayed versions are evenly distributed along a single period of said reference clock signal.

6. The synthesizer as recited in claim 1 wherein said tap-select logic comprises an up/down counter that traverses said taps sequentially.

7. The synthesizer as recited in claim 1 wherein said tap-select logic cycles through all of said taps to generate said local clock signal.

8. A method of generating fractional frequency local clock signals, comprising:
generating a reference clock signal;
providing progressively delayed versions of said reference clock signal at taps of a delay circuit; and
traversing said taps to generate said local clock signal from said progressively delayed versions.

9. The method as recited in claim 8 wherein said reference clock signal has a frequency lower than a frequency of said local clock signal.

10. The method as recited in claim 8 wherein said delay circuit is a delay-locked loop.

11. The method as recited in claim 8 wherein said delay circuit has at least 32 taps.

12. The method as recited in claim 8 wherein delays of said progressively delayed versions are evenly distributed along a single period of said reference clock signal.

13. The method as recited in claim 8 wherein an up/down counter traverses said taps sequentially.

14. The method as recited in claim 8 wherein said tap-select logic cycles through all of said taps to generate said local clock signal.

15. A synchronous telecommunications system, comprising:
circuitry for receiving an input clock signal and synchronous data from a remote source;
a reference clock source that generates a reference clock signal;
a delay circuit, coupled to said reference clock source and having taps, that provides progressively delayed versions of said reference clock signal at said taps;
tap-select logic, coupled to said delay circuit, that traverses said taps to generate said local clock signal from said progressively delayed versions; and
data processing circuitry for processing said synchronous data based on said local clock signal.

16. The system as recited in claim 15 wherein said reference clock signal has a frequency lower than a frequency of said local clock signal.

17. The system as recited in claim 15 wherein said delay circuit is a delay-locked loop.

18. The system as recited in claim 15 wherein said delay circuit has at least 32 taps.

19. The system as recited in claim 15 wherein delays of said progressively delayed versions are evenly distributed along a single period of said reference clock signal.

20. The system as recited in claim 15 wherein said tap-select logic comprises an up/down counter that traverses said taps sequentially.

21. The system as recited in claim 15 wherein said tap-select logic cycles through all of said taps to generate said local clock signal.
